(19) United States
(12) Patent Application Publication
(10) Pub. No.: US 2023/0220583 A1
(43) Pub. Date: Jul. 13, 2023

(54) SINGLE CRYSTAL PRODUCTION APPARATUS AND SINGLE CRYSTAL PRODUCTION METHOD

(71) Applicant: SUMCO Corporation, Tokyo (JP)

(72) Inventors: Kenichi Nishioka, Tokyo (JP); Keiichi Takanashi, Tokyo (JP); Ken Hamada, Tokyo (JP); Ippei Shimozaki, Tokyo (JP)

(73) Assignee: SUMCO Corporation, Tokyo (JP)

(21) Appl. No.: 17/996,737

(22) PCT Filed: Jan. 6, 2021
(86) PCT No.: PCT/JP2021/000220

§ 371 Date: Oct. 20, 2022

(30) Foreign Application Priority Data
Apr. 20, 2020 (JP) 2020-074514

(51) Int. Cl. C30B 15/26; C30B 29/06; G01B 11/10

(52) U.S. Cl. CPC C30B 15/26; C30B 29/06; G01B 11/105

(57) ABSTRACT

A single crystal manufacturing apparatus 10 according to the present invention is provided with a single crystal puller pulling up a single crystal 15 from a melt 13, a camera 18 photographing a fusion ring generated at the boundary between the melt 13 and the single crystal 15 and an computer 24 processing a photographed image taken by the camera 18. The computer 24 projects and converts the fusion ring appearing in the photographed image taken by the camera 18 on a reference plane corresponding to the liquid level position of the melt based on an installation angle and a focal length of the camera and calculates a diameter of the single crystal 15 from a shape of the fusion ring on the reference plane.

### TECHNICAL FIELD

The present invention relates to a single crystal manufacturing apparatus and method for manufacturing a single crystal by a Czochralski method (CZ method) and, more particularly, to diameter measurement of a single crystal during a crystal pull-up process.

### BACKGROUND ART

Most of the silicon wafers used as substrate materials for semiconductor devices are manufactured by a CZ method. In the CZ method, a polycrystalline silicon raw material is heated in a quartz crucible to generate a silicon melt, and a seed crystal is lowered from above the silicon melt and immersed in the silicon melt. Then, the seed crystal is gradually lifted up while being rotated together with the quartz crucible, whereby a large single crystal grows at the lower end of the seed crystal. According to the CZ method, it is possible to produce a large-diameter silicon single crystal with a high yield.

Single crystal ingots are manufactured aiming at a certain diameter. For example, if the final product is a 300 mm wafer, it is common to grow a single crystal ingot of 305 mm to 320 mm, which is slightly larger than the diameter. After that, the single crystal ingot is externally ground into a columnar shape, sliced into a wafer shape, and then subjected to a chamfering process to finally obtain a wafer having a target diameter. As described above, the target diameter of the single crystal ingot must be larger than the wafer diameter of the final product, but if it is too large, the grinding allowance increases and it becomes uneconomical. Therefore, a single crystal ingot having a diameter as small as possible but larger than the wafer is required.

In the CZ method, a single crystal is pulled up while controlling crystal pull-up conditions so that the crystal diameter becomes constant. Regarding the control of the diameter of a single crystal, for example, Patent Document 1 describes a method of accurately measuring the diameter of a growing single crystal by processing an image of the interface between the single crystal and the melt. In this method, crucible rotation speed, crystal rotation speed, crystal pull-up speed, crucible rising speed, melt temperature (heater power), and the like are controlled so that the diameter of the single crystal becomes a target diameter.

Further, Patent Document 2, which relates to the measurement of a melt level position, describes a method of calculating the representative dimensions of the respective real image and mirror image of an in-furnace structure in a chamber appearing on a photographed image of the in-furnace structure and a melt level which is taken with a camera installed outside the chamber. In this method, the edge pattern of the real image of the in-furnace structure appearing on the photographed image and the edge pattern of the mirror image of the in-furnace structure appearing on the melt surface are detected. Then, based on the installation angle and focal length of the camera, the edge patterns of the respective real and mirror images of the in-furnace structure are projected and converted on a reference plane, followed by pattern matching on the edge patterns of the respective real and mirror images of the in-furnace structure on the reference plane. Then, from the shape of the reference pattern having a maximum matching rate, the representative dimensions of the respective real and mirror images of the in-furnace structure are calculated.

### CITATION LIST

### Patent Document

Patent Document 1: Japanese Patent No. 4,253,123
Patent Document 2: Japanese patent application laid open No. 2018-090451

### SUMMARY OF THE INVENTION

### Problem to be Solved by the Invention

In the single crystal pull-up control according to the CZ method, the diameter of the single crystal is measured from the image taken by the camera installed outside the furnace, and the diameter of the single crystal is controlled so as to make the measured value of the diameter coincide with a diameter profile, so that diameter measurement is required to be performed with high accuracy. As illustrated in FIG. 8, in the conventional diameter measurement method, a scanning line SL for measuring the diameter in the horizontal direction is set in the camera image, and the edge of a fusion ring FR is detected from the intersection between the brightness distribution on the scanning line SL and a threshold value TH (slice level). Then, a width w between two intersections P_{L} and P_{R} between the scanning line SL and the edge of the fusion ring FR and a distance h from a crystal center position C_{O} to the scanning line SL are used to calculate a diameter D (=2(w²+4h²)^{1/2}) of the fusion ring. Since the unit of the diameter value D of the fusion ring thus obtained is the number of pixels, the crystal diameter value converted into the actual unit (mm) can be obtained by multiplying the diameter D by the diameter conversion coefficient.

As described above, since the crystal diameter information obtained from the camera image is represented by a pixel, it is necessary to convert it into an actual diameter unit (mm). However, the diameter conversion coefficient used for unit conversion is created based on the crystal diameter value visually measured by the operator with a telescope during a single crystal pull-up process, so that the unit conversion accuracy is poor, which may cause a large calculation error of the diameter.

It is therefore an object of the present invention to provide a single crystal manufacturing apparatus and method capable of improving the measurement accuracy of the crystal diameter.

### Means for Solving the Problems

In order to solve the above problem, a single crystal manufacturing apparatus according to the present invention includes: a single crystal puller pulling up a single crystal from a melt; a camera photographing a fusion ring generated at the boundary between the melt and the single crystal; and an computer processing a photographed image taken by the camera, wherein the computer projects and converts the fusion ring appearing in the photographed image taken by the camera on a reference plane corresponding to the liquid level position of the melt based on an installation angle and a focal length of the camera and calculates a diameter of the single crystal from a shape of the fusion ring on the reference plane.

According to the present invention, it is possible to accurately calculate the actual diameter of the single crystal without using a diameter conversion coefficient for unit-converting the diameter measurement value obtained from the photographed image taken by the camera. This makes it possible to improve the measurement accuracy of the diameter of the single crystal during a crystal pull-up step.

In the present invention, the computer preferably projects and converts an edge pattern of the fusion ring detected based on a predetermined threshold value for the brightness distribution of the photographed image on the reference plane. This makes it possible to accurately grasp the shape of the fusion ring.

In the present invention, the threshold value is preferably a value obtained by multiplying the peak value of brightness in the photographed image by a value smaller than 1, and the computer preferably sets, in the photographed image, a horizontal scanning line intersecting the fusion ring and detects an outer intersection (one point near the outer periphery of the photographed image) between brightness distribution on the horizontal scanning line and the threshold value as the edge pattern of the fusion ring.

In the present invention, the computer preferably calculates the diameter of the single crystal based on a distance between two intersections of the edge pattern of the fusion ring projected on the reference plane and a predetermined diameter measurement line and a distance from the center position of the single crystal to the diameter measurement line. This makes it possible to geometrically calculate the diameter of the fusion ring and thereby to calculate the diameter of the single crystal from the diameter of the fusion ring.

In the present invention, the computer preferably approximates the edge pattern of the fusion ring to a circle and calculates the diameter of the single crystal from the diameter of the approximate circle of the fusion ring. This makes it possible to improve the measurement accuracy of the diameter of the fusion ring.

In the present invention, the computer preferably calculates the diameter of the crystal under room temperature by subtracting a predetermined correction amount from the diameter during the pull-up process of the single crystal or multiplying the diameter during the pull-up process of the single crystal by a predetermined correction coefficient. This makes it possible to control the crystal diameter based on the diameter of the single crystal under room temperature.

In the present invention, the computer preferably changes the correction amount or the correction coefficient according to a change in the furnace structure, the position of the liquid level, or the length of the single crystal. This allows the crystal diameter to be accurately measured according to a change in the growing condition of the single crystal.

Further, a single crystal manufacturing method according to the present invention is a manufacturing method of a single crystal by a CZ method and includes: a step of photographing a fusion ring generated at the boundary between a melt and a single crystal with a camera; and a step of calculating a diameter of the single crystal by processing a photographed image taken by the camera, wherein the step of calculating the diameter of the single crystal projects and converts the fusion ring appearing in the photographed image taken by the camera on a reference plane corresponding to the liquid level position of the melt based on an installation angle and a focal length of the camera and calculates the diameter of the single crystal from a shape of the fusion ring on the reference plane.

According to the present invention, it is possible to accurately calculate the actual diameter of the single crystal without using a diameter conversion coefficient for unit-converting a diameter measurement value obtained from the photographed image taken by the camera. This makes it possible to improve the measurement accuracy of the diameter of the single crystal during a crystal pull-up step.

In the present invention, the step of calculating the diameter of the single crystal preferably projects and converts an edge pattern of the fusion ring detected based on a predetermined threshold value with respect to the brightness distribution of the photographed image on the reference plane. This makes it possible to accurately grasp the shape of the fusion ring.

In the present invention, the threshold value is preferably a value obtained by multiplying the peak value of brightness in the photographed image by a value smaller than 1, and the step of calculating the diameter of the single crystal preferably sets, in the photographed image, a horizontal scanning line intersecting the fusion ring and detects an outer intersection (one point near the outer periphery of the photographed image) between brightness distribution on the horizontal scanning line and the threshold value as the edge pattern of the fusion ring.

In the present invention, the step of calculating the diameter of the single crystal preferably calculates the diameter of the single crystal based on a distance between two intersections of the edge pattern of the fusion ring projected on the reference plane and a predetermined diameter measurement line and a distance from the center position of the single crystal to the diameter measurement line. This makes it possible to geometrically calculate the diameter of the fusion ring and thereby to calculate the diameter of the single crystal from the diameter of the fusion ring.

In the present invention, the step of calculating the diameter of the single crystal preferably approximates the edge pattern of the fusion ring to a circle and calculates the diameter of the single crystal from the diameter of the approximate circle of the fusion ring. This can improve the measurement accuracy of the diameter of the fusion ring.

In the present invention, the step of calculating the diameter of the single crystal preferably calculates the diameter of the crystal under room temperature by subtracting a predetermined correction amount from the diameter during the pull-up process of the single crystal or multiplying the diameter during the pull-up process of the single crystal by a predetermined correction coefficient. This allows the crystal diameter to be controlled based on the diameter of the single crystal under room temperature.

In the present invention, the step of calculating the diameter of the single crystal preferably changes the correction amount or the correction coefficient according to a change in the furnace structure, the position of the liquid level, or the length of the single crystal. This allows the crystal diameter to be accurately measured according to a change in the growing condition of the single crystal.

### Effects of the Invention

According to the present invention, it is possible to provide a single crystal manufacturing apparatus and method capable of improving the measurement accuracy of the crystal diameter.

### BRIEF DESCRIPTION OF THE DRAWINGS

FIG. 1 is a schematic cross-sectional view illustrating the configuration of a single crystal manufacturing apparatus according to an embodiment of the present invention.

FIG. 2 is a flowchart for explaining a method of manufacturing a silicon single crystal using the single crystal manufacturing apparatus 10.

FIG. 3 is a side view illustrating the shape of the silicon single crystal ingot manufactured using the manufacturing method illustrated in FIG. 2.

FIG. 4 is a photographed image taken by the camera 18 and is a view for explaining a fusion ring generated at the solid-liquid interface.

FIG. 5 is a schematic view for explaining a method of projecting and converting the two-dimensional coordinates of a photographed image into the coordinates of a real space.

FIG. 6 is a diagram for explaining a method of calculating the diameter according to the present embodiment.

FIG. 7 is a schematic diagram for explaining a method of calculating the gap value ΔG from radii r_{f} and rₘ of the respective openings in the real image Ma and mirror image Mb of the heat shield member 17.

FIG. 8 is a diagram for explaining a conventional method of calculating the diameter.

### MODE FOR CARRYING OUT THE INVENTION

Hereinafter, preferred embodiments of the present invention will be described in detail with reference to the accompanying drawings. It should be noted that the embodiments shown below are described concretely for a better understanding of the gist of the invention, and the present invention is not limited to the embodiments unless otherwise specified. In addition, the drawings used in the following description may be illustrated by enlarging the main parts in order to make the features of the present invention easy to understand, and the dimensional ratios of the respective components are not always the same as the actual ones.

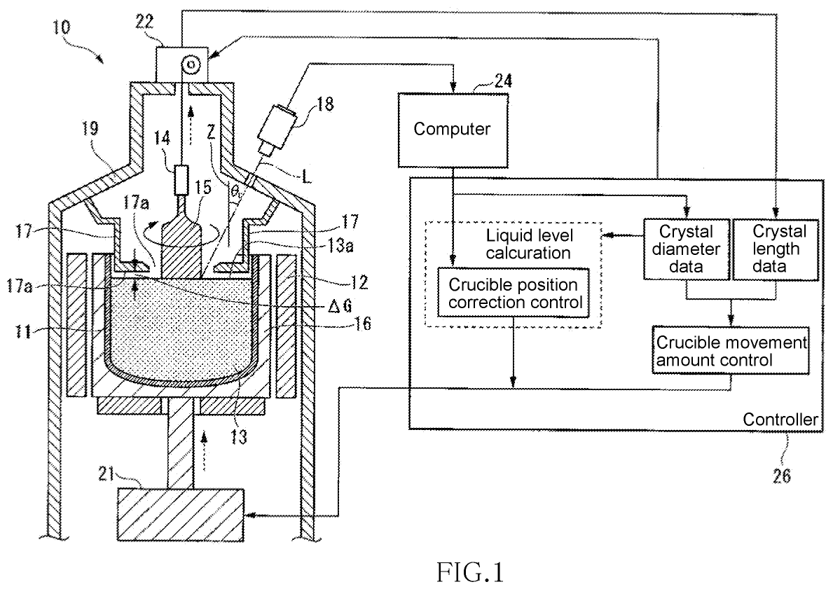

FIG. 1 is a schematic cross-sectional view illustrating the configuration of a single crystal manufacturing apparatus according to an embodiment of the present invention.

As illustrated in FIG. 1, a single crystal manufacturing apparatus 10 is an apparatus for growing a silicon single crystal and includes a substantially cylindrical chamber 19, and a quartz crucible 11 in which a silicon melt 13 is stored is installed inside the chamber 19. The chamber 19 may have, for example, a double-walled structure having a certain gap formed inside. By flowing cooling water through the gap, it is possible to prevent the chamber 19 from becoming hot when the quartz crucible 11 is heated.

An inert gas such as argon is introduced into the chamber 19 from before the start of pulling up the silicon single crystal to after the end thereof. A pull-up drive 22 is provided at the top of the chamber 19. The pull-up drive 22 pulls up a seed crystal 14 that is the growth nucleus of a silicon single crystal ingot 15 and the silicon single crystal ingot 15 that grows from the seed crystal 14 while rotating them. The pull-up drive 22 may be provided with a sensor (not illustrated) that transmits crystal length information of the silicon single crystal ingot 15 based on the pull-up amount of the silicon single crystal ingot 15. The pull-up drive 22 is connected to a controller 26, and the crystal length information is transmitted to the controller 26. In the present embodiment, the components in the chamber 19 such as the quartz crucible 11 and the pull-up drive 22 constitute a single crystal puller.

Inside the chamber 19, a substantially cylindrical heater 12 is arranged so as to surround the quartz crucible 11. The heater 12 heats the quartz crucible 11. A crucible support (graphite crucible) 16 and the quartz crucible 11 are housed inside the heater 12. The quartz crucible 11 is a substantially cylindrical container entirely formed of quartz, in which the upper part forms an open surface.

The silicon melt 13 in which solid silicon is melted is stored in the quartz crucible 11. For example, the crucible support 16 is entirely made of graphite and is closely supported so as to wrap the quartz crucible 11. The crucible support 16 maintains the shape of the quartz crucible 11 softened when the silicon is melted and supports the quartz crucible 11.

A crucible lift device 21 is provided under the crucible support 16. The crucible lift device 21 supports the crucible support 16 and the quartz crucible 11 from below and moves up and down the quartz crucible 11 such that the liquid level position of a melt surface 13a of the silicon melt 13 that changes as the silicon single crystal ingot 15 is pulled up becomes an appropriate position, whereby the position of the melt surface 13a of the silicon melt 13 is controlled. At the same time, the crucible lift device 21 rotatably supports the crucible support 16 and the quartz crucible 11 at a predetermined rotation speed during pull-up.

A heat shield member (shielding cylinder) 17 is formed on the upper surface of the quartz crucible 11 so as to cover the upper surface of the silicon melt 13, i.e., the melt surface 13a. The heat shield member 17 is made of, for example, a mortar-shaped heat insulating plate, and a substantially circular opening 17a is formed at the lower end thereof. The outer edge of the upper end of the heat shield member 17 is fixed to the inner surface side of the chamber 19.

The heat shield member 17 prevents the pulled-up silicon single crystal ingot 15 from receiving radiant heat from the silicon melt 13 in the quartz crucible 11 to change the heat history and deteriorate the quality. Further, the heat shield member 17 induces a pull-up atmosphere gas introduced into the chamber 19 from the silicon single crystal ingot 15 side to the silicon melt 13 side, thereby controlling the amount of residual oxygen in the vicinity of the melt surface 13a of the silicon melt 13 and silicon vapor, SiO, and the like evaporated from the silicon melt 13 so that the silicon single crystal ingot 15 has the desired quality. It is considered that the control of such a pull-up atmosphere gas depends on the pressure inside the furnace and the flow rate of the gas when passing through the gap between the lower end of the heat shield member 17 and the melt surface 13a of the silicon melt 13. A distance (gap value) ΔG from the lower end of the heat shield member 17 to the melt surface 13a of the silicon melt 13 needs to be set accurately so that the silicon single crystal ingot 15 has the desired quality. As the pull-up atmosphere gas, an inert gas such as argon may contain hydrogen, nitrogen, or any other predetermined gas as the dopant gas.

A camera 18 is installed outside the chamber 19. The camera 18 is, for example, a CCD camera, and photographs the inside of the chamber 19 through an observation window formed in the chamber 19. The installation angle θ_{c} of the camera 18 is a predetermined angle with respect to a pull-up axis Z of the silicon single crystal ingot 15, and the camera 18 has an optical axis L inclined with respect to the vertical direction. In other words, the installation angle θ_{c} of the camera 18 is the inclination angle of the optical axis L with respect to the vertical direction. The camera 18 photographs the upper surface region of the quartz crucible 11, including the opening 17a of the heat shield member 17 and the melt surface 13a, from diagonally above. The camera 18 is connected to an computer 24, and an image taken by the camera 18 is used by the computer 24 to detect the crystal diameter and the liquid level position.

The computer 24 calculates the liquid level position of the silicon melt 13 based on an image including the real image of the heat shield member 17 taken by the camera 18 and the mirror image of the heat shield member 17 projected on the melt surface 13a of the silicon melt 13. Further, the computer 24 calculates the diameter of the silicon single crystal ingot based on an image including the boundary portion between the silicon melt 13 and the silicon single crystal ingot 15 taken by the camera 18. The computer 24 is connected to the controller 26, and the calculation result is transmitted to the controller 26 from the computer 24.

The controller 26 controls the moving amount (rising amount) of the quartz crucible 11 based on the crystal length data of the silicon single crystal ingot 15 obtained from a sensor of the pull-up drive 22 and the crystal diameter data calculated by the computer 24. Further, in order to control the movement amount of the quartz crucible 11, the controller 26 performs position correction control of the quartz crucible 11 based on the liquid level position of the silicon melt 13 calculated by the computer 24.

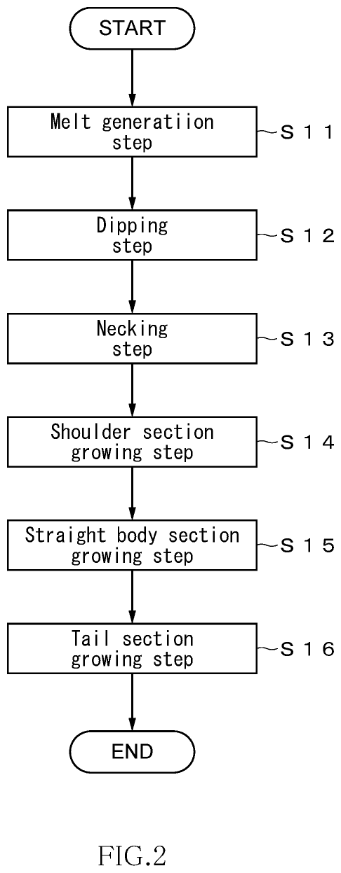

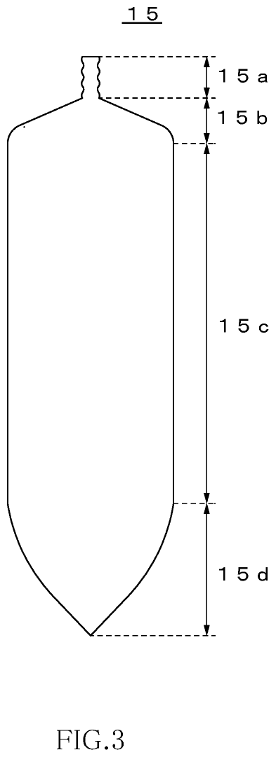

FIG. 2 is a flowchart for explaining a method of manufacturing a silicon single crystal using the single crystal manufacturing apparatus 10. FIG. 3 is a side view illustrating the shape of the silicon single crystal ingot manufactured using the manufacturing method illustrated in FIG. 2.

As illustrated in FIG. 2, in the manufacture of a silicon single crystal, first, a raw material polycrystalline silicon is put into the quartz crucible 11, and the polycrystalline silicon in the quartz crucible 11 is heated and melted by the heater 12 to generate the silicon melt 13 (step S11).

Next, the seed crystal 14 is lowered and dipped in the silicon melt 13 (step S12). Then, a crystal pull-up step (steps S13 to S16) is carried out, in which the seed crystal 14 is gradually pulled up while maintaining the contact state with the silicon melt 13 to grow a single crystal.

In the crystal pull-up step, a necking step S13, a shoulder section growing step S14, a straight body section growing step S15, and a tail section growing step S16 are performed in this order. The necking step S13 forms a neck section 15a having a narrowed crystal diameter for non-dislocation. The shoulder section growing step S14 forms a shoulder section 15b having a gradually increasing crystal diameter. The straight body section growing step S15 forms a straight body section 15c in which the crystal diameter is maintained at a specified diameter (for example, about 300 mm). The tail section growing step S16 forms a tail section 15d in which the crystal diameter is gradually reduced. Finally, the single crystal is separated from the melt surface. As a result, the silicon single crystal ingot 15 illustrated in FIG. 3 having the neck section 15a, shoulder section 15b, straight body section 15c, and tail section 15d is completed.

During the crystal pull-up process, the gap value ΔG between the melt surface 13a of the silicon melt 13 and the heat shield member 17 is calculated from the image taken by the camera 18, whereby the liquid level position of the silicon melt 13 is calculated. Then, based on this gap value ΔG, the rising amount of the crucible is controlled. As a result, the position of the melt surface 13a with respect to the in-furnace structure such as the heater 12 and heat shield member 17 is kept constant or changed from the start to the end of the pull-up of the silicon single crystal regardless of a reduction in the amount of the silicon melt 13, whereby the radiation distribution of heat with respect to the silicon melt 13 can be controlled.

Further, during the crystal pull-up process, the diameter of the single crystal is calculated from the image taken by the camera 18, and crystal pull-up conditions are controlled so that the crystal diameter becomes a predetermined diameter corresponding to the crystal length. In the shoulder section growing step S14, the crystal diameter is controlled so as to be gradually increased; in the straight body section growing step S15, the crystal diameter is controlled so as to be constant; and in the tail section growing step S16, the crystal diameter is controlled so as to be gradually reduced. The control target of the crystal pull-up conditions includes the height position of the quartz crucible 11, crystal pull-up speed, heater output, and the like. The control of the pull-up conditions using the image taken by the camera 18 is performed during the crystal pull-up step. Specifically, it is performed between the start of the necking step S13 in FIG. 2 and the end of the tail section growing step S16.

The following describes in detail the method of calculating the crystal diameter from the image taken by the camera 18.

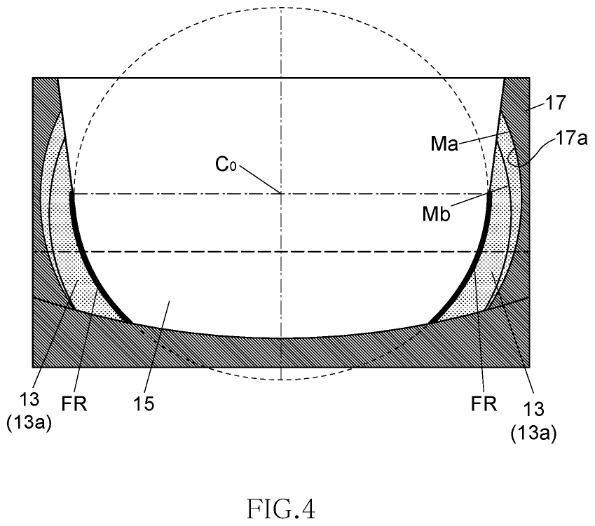

FIG. 4 is a photographed image taken by the camera 18 and is a view for explaining a fusion ring generated at the solid-liquid interface.

As illustrated in FIG. 4, the silicon melt 13 can be seen through the opening 17a of the heat shield member 17, and a part of the heat shield member 17 is reflected in the photographed image. Further, there is the silicon single crystal 15 inside the opening 17a of the heat shield member 17, and the silicon melt 13 can be seen through a slight gap between the heat shield member 17 and the silicon single crystal 15. Further, a fusion ring FR is generated at the boundary between the silicon single crystal 15 and the silicon melt 13. The fusion ring FR is a ring-shaped high-luminance region generated by reflection of the radiated light from the heater 12 and the like by the meniscus at the solid-liquid interface. In the photographed image, the heat shield member 17 is fixed to the chamber 19 and is thus not changed in position, whereas the position and size of the fusion ring FR change depending on a change in the crystal diameter or liquid level position. When the liquid level position is constant, the larger the crystal diameter is, the greater the fusion ring FR becomes. When the crystal diameter is constant, the crystal diameter decreases as the liquid level position lowers. In this way, the outline of the single crystal in the vicinity of the solid-liquid interface can be captured from the fusion ring FR, allowing the diameter of the single crystal to be calculated.

A mirror image Mb of the heat shield member 17 is reflected on the melt surface 13a of the silicon melt 13. The mirror image Mb of the heat shield member 17 changes according to the distance from the heat shield member 17 to the melt surface 13a. Therefore, although the distance between areal image Ma of the heat shield member 17 and the mirror image Mb reflected on the melt surface 13a changes with the vertical movement of the melt surface 13a due to the consumption of the silicon melt 13 in association with crystal growth or due to the vertical movement of the melt surface 13a in association with the elevating and lowering of the quartz crucible 11, the position of the melt surface 13a is at the midpoint between the real image Ma and the mirror image Mb. Therefore, for example, when the melt surface 13a is aligned with the lower end of the heat shield member 17, the distance between the real image Ma and the mirror image Mb of the heat shield member 17 becomes zero, and when the melt surface 13a is gradually lowered, distance (gap value) ΔG from the lower end of the heat shield member 17 to the melt surface 13a also gradually increases. The gap value ΔG at this time can be calculated as a value of ½ of the distance D between the real image Ma and the mirror image Mb of the heat shield member 17 (that is, D=ΔG×2). As described above, the liquid level position of the silicon melt 13 can be obtained as the distance from the lower end of the heat shield member 17.

When measuring the diameter of a single crystal from the fusion ring FR, the edge pattern of the fusion ring FR is detected from the image taken by the camera 18, and the crystal diameter is calculated from the edge pattern of the fusion ring FR. The diameter value of the fusion ring FR can be obtained from an approximate circle obtained by approximating the edge pattern (sample value) by the least squares method. By further correcting the diameter of the fusion ring FR thus obtained, the diameter of the single crystal at room temperature can be calculated.

When measuring the crystal diameter, stable detection of the fusion ring FR is indispensable. As a method of detecting the position of a predetermined image from the image data, a method of setting a threshold value based on the brightness value of the image and performing binarization processing is common. However, when the edge detection of the fusion ring FR is performed by the binarization process, the detection position may shift due to the change in brightness accompanying a change in the temperature inside the furnace.

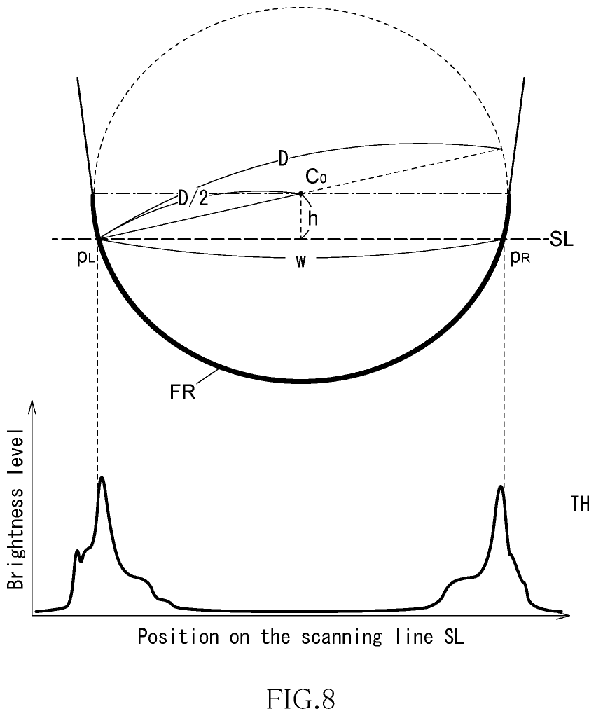

In order to eliminate this effect, it is preferable to detect the edge of the fusion ring FR from a threshold value (slice level) determined by finding the peak value (peak brightness of the fusion ring FR) of the brightness in the photographed image and multiplying this peak brightness by a value smaller than 1 instead of the general binarization method. That is, in the detection of the edge pattern (contour line) of the fusion ring FR, by changing the threshold value (slice level) according to the brightness of the fusion ring FR in the image, it is possible to reduce the measurement error due to the influence of the brightness change and thereby to stably detect and specify the exact dimensions of the fusion ring FR. Specifically, a horizontal scanning line SL that intersects the fusion ring FR is set as in FIG. 8, and an outer intersection (one point near the outer periphery of the photographed image) between the brightness distribution on the horizontal scanning line SL and the threshold value (corresponding to TH in FIG. 8) is detected as the edge of the fusion ring FR.

Since the camera 18 installed outside the chamber 19 photographs the melt surface 13a from diagonally above, the apparent shape of the fusion ring FR is not a perfect circle but is distorted. In order to accurately calculate the diameter of the fusion ring FR, it is necessary to correct the distortion of the image. Therefore, in the present embodiment, the edge pattern of the fusion ring FR taken by the camera 18 is projected and converted on a reference plane, and the diameter of the fusion ring FR when viewed from directly above is obtained. The reference plane is the liquid level (horizontal plane) of the silicon melt 13 and can be obtained from the real image Ma and mirror image Mb of the heat shield member 17 as described above.

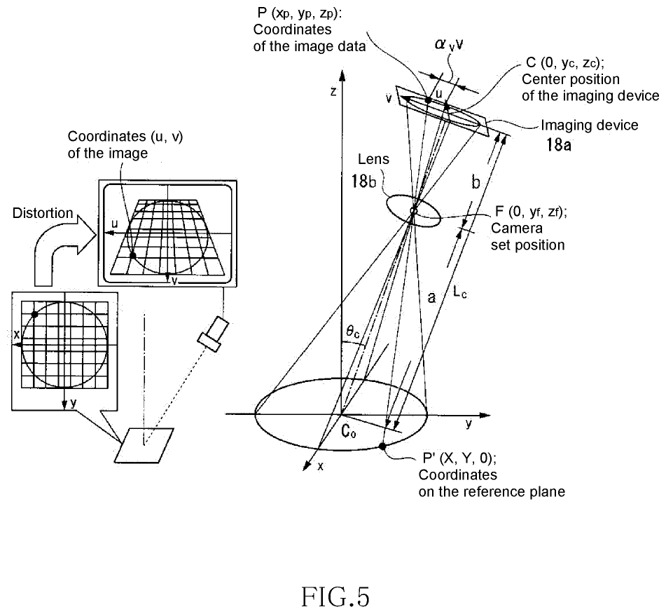

FIG. 5 is a schematic view for explaining a method of projecting and converting the two-dimensional coordinates of a photographed image into the coordinates of a real space.

As illustrated on the left side of FIG. 5, the camera 18 photographs the inside of the chamber 19 from diagonally above, so that the shape of the fusion ring in the photographed image is distorted, resulting in an image with a sense of perspective. That is, the image on the lower side, which is close to the camera 18, is wider than the image on the upper side. Therefore, in order to accurately calculate the dimensions of the fusion ring, it is necessary to correct the distortion of the image. Thus, the coordinates of the photographed image taken by the camera 18 are projected and converted into the coordinates on the reference plane set at the same height position as the melt surface 13a to correct the distortion.

The right side of FIG. 5 illustrates a coordinate system for performing image correction. In this coordinate system, the reference plane is set to the xy plane. Further, an origin C₀ of the XY coordinates is the intersection between the reference plane and the straight line (dash-dot-dash line) passing from a center position C (0, y_{c}, z₀) of an imaging device 18a of the camera 18 to a center position F (0, y_{f}, z_{f}) of a lens 18b of the camera 18. This straight line is the optical axis of the camera 18.

Further, the pull-up direction of the silicon single crystal 15 is the positive direction of the z-axis, which is the vertical axis, and the center position C (0, y_{c}, z_{c}) of the imaging device 18a and the center position F (0, y_{f}, z_{f}) of the lens 18b are in the yz plane. The coordinates (u, v) in the image illustrated on the left side of FIG. 5 are represented by the pixels of the imaging device 18a and correspond to any one point P (xₚ, yₚ, zₚ) on the imaging device 18a shown in the following equation (1).

$$\begin{matrix}[ Numeral 1 ] & \\ \begin{matrix}{x}_{p} = - {a}_{u} u \\ {y}_{p} = {y}_{c} - {a}_{v} v cos {θ}_{c} \\ {z}_{p} = {z}_{c} + {a}_{v} v sin {θ}_{c}\end{matrix} \} & ( 1 )\end{matrix}$$

Here, αᵤ and αᵥ are the pixel sizes in the horizontal and vertical directions of the imaging device 18a, and y_{c} and z_{c} are the y and z coordinates of the center position C of the imaging device 18a. Further, as illustrated on the right side of FIG. 5, θ_{c} is the angle formed by the optical axis of the camera 18 and the z axis, and is an installation angle of the camera 18.

Further, the center position C (0, y_{C}, z_{c}) of the imaging device 18a is represented by the following equation (2) using the center position F (0, y_{f}, z_{f}) of the lens 18b of the camera 18 and a focal length fₗ of the lens.

$$\begin{matrix}[ Numeral 2 ] & \\ \begin{matrix}{y}_{c} = \sqrt{{y}_{f}^{2} + {z}_{f}^{2}} [ 1 + {f}_{l} / ( \sqrt{{y}_{f}^{2} + {z}_{f}^{2}} - {f}_{l} ) ] sin {θ}_{c} \\ {z}_{c} = \sqrt{{y}_{f}^{2} + {z}_{f}^{2}} [ 1 + {f}_{l} / ( \sqrt{{y}_{f}^{2} + {z}_{f}^{2}} - {f}_{l} ) ] cos {θ}_{c}\end{matrix} \} & ( 2 )\end{matrix}$$

Here, the equation (2) will be described in detail. When the distance from the coordinate origin C₀ on the reference plane to the center position C (0, y_{c}, z_{c}) of the imaging device 18a is L_{c}, y_{c}, z_{c} are as shown in the following equation (3), respectively.

$$\begin{matrix}[ Numeral 3 ] & \\ \begin{matrix}{y}_{c} = {L}_{c} sin {θ}_{c} \\ {z}_{c} = {L}_{c} cos {θ}_{c}\end{matrix} \} & ( 3 )\end{matrix}$$

When the distance from the coordinate origin C₀ to the center position F of the lens 18b of the camera 18 is a, and the distance from the center position F of the lens 18b to the center position C of the imaging device 18a is b, a distance L_{c} from the coordinate origin C₀ to the center position C of the imaging device 18a is as shown in the following equation (4).

[Numeral 4]

L_{c}=a+b (4)

From the lens imaging formula, the focal length fₗ is represented by the following equation (5) using the distances a and b.

$$\begin{matrix}[ Numeral 4 ] & \\ \frac{1}{{f}_{l}} = \frac{1}{a} + \frac{1}{b} & ( 4 )\end{matrix}$$

When the distance b is deleted from the equations (4) and (5), and L_{c} is represented by the distance a and focal length fₗ, the following equation (6) is obtained.

$$\begin{matrix}[ Numeral 6 ] & \\ {L}_{c} = a + \frac{{af}_{l}}{a - {f}_{l}} & ( 6 )\end{matrix}$$

The value of the distance a from the coordinate origin C₀ to the center position F of the lens 18b of the camera 18 can be represented by the following equation (7) using the center position F (0, y_{f}, z_{f}) of the lens 18b of the camera 18.

[Numeral 7]

a=\sqrt{y_{f}²+z_{f}²} (7)

Therefore, the above equation (2) can be obtained from the equations (3), (6) and (7).

When the lens 18b is considered as a pinhole, any one point P (xₚ, xₚ, xₚ) on the imaging device 18a is projected on the reference plane through F (0, y_{f}, z_{f}), and this projection point P′ (X, Y, 0) can be represented by the following equation (8).

$$\begin{matrix}[ Numeral 8 ] & \\ \begin{matrix}X = - {x}_{p} {z}_{f} / ( {z}_{p} - {z}_{f} ) \\ Y = ( {y}_{f} {z}_{p} - {y}_{p} {z}_{f} ) / ( {z}_{p} - {z}_{f} )\end{matrix} \} & ( 8 )\end{matrix}$$

By using equations (1), (2) and (8), the coordinates of the fusion ring projected on the reference plane can be obtained.

When the distance b from the center position F (0, y_{f}, z_{f}) of the lens 18b to the center position C (0, y_{c}, z_{c}) of the imaging device 18a is known, the coordinates y_{f} and z_{f} of the center position F of the lens 18b can be represented by the following equation (9) using the distance b and the coordinates y_{c} and z_{c} of the center position C of the imaging device 18a.

$$\begin{matrix}[ Numeral 9 ] & \\ \begin{matrix}{y}_{f} = b sin {θ}_{c} - {y}_{c} \\ {z}_{f} = b cos {θ}_{c} - {z}_{c}\end{matrix} \} & ( 9 )\end{matrix}$$

As described above, when the distance b (back distance) from the center position F (principal point) of the lens 18b to the center position C of the imaging device 18a is known, the projection point P′ (X, Y, 0) can be represented by using the value of the back distance.

The following describes a method of calculating the radius of the fusion ring. The least squares method may be used as a method of calculating the coordinates (x₀, y₀) of the center position and radius r of the fusion ring from the coordinates of the fusion ring projected on the reference plane. The fusion ring is circular, and its image satisfies a circular equation shown in the following equation (10).

[Numeral 10]

(x−x₀)²+(y−y₀)²=r² (10)

Here, the least squares method is used to calculate (x₀, y₀) and r in the equation (10). In order to easily perform the calculation by the least squares method, the transformation shown in the following equation (11) is performed.

$$\begin{matrix}[ Numeral 11 ] & \\ z = a + bx + cy & ( 11 )\end{matrix}$$

$$\begin{matrix}z = {x}^{2} + {y}^{2} \\ a = {r}^{2} - {x}_{0}^{2} - {y}_{0}^{2} \\ b = 2 {x}_{0} \\ c = 2 {y}_{0}\end{matrix} \}$$

The variables a, b, and c in this equation (11) are obtained by the least squares method, which obtains a condition that the sum of squares of the difference between the equation (11) and the measured point is minimized, and can be calculated by solving the partial differential equation shown in the following equation (12).

$$\begin{matrix}[ Numeral 12 ] & \\ \frac{\partial }{\partial a , b , c} {\sum }_{i} {( a + {bx}_{i} + {cy}_{i} - {z}_{i} )}^{2} = 0 & ( 12 )\end{matrix}$$

Then, the solution of this equation (12) can be calculated by the simultaneous equations shown in the following equation (13).

$$\begin{matrix}[ Numeral 13 ] & \\ ( \begin{matrix}{\sum }_{i} {z}_{i} \\ {\sum }_{i} {z}_{i} {x}_{i} \\ {\sum }_{i} {z}_{i} {y}_{i}\end{matrix} ) = ( \begin{matrix}n & {\sum }_{i} {x}_{i} & {\sum }_{i} {y}_{i} \\ {\sum }_{i} {x}_{i} & {\sum }_{i} {x}_{i}^{2} & {\sum }_{i} {x}_{i} {y}_{i} \\ {\sum }_{i} {y}_{i} & {\sum }_{i} {x}_{i} {y}_{i} & {\sum }_{i} {x}_{i}^{2}\end{matrix} ) ( \begin{matrix}a \\ b \\ c\end{matrix} ) & ( 13 )\end{matrix}$$

By using the least squares method in this way, it is possible to calculate the approximate circle of the fusion ring projected on the reference plane.

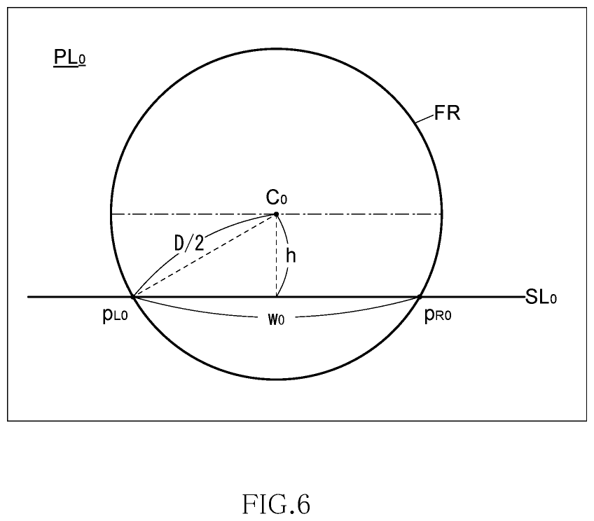

Then, the diameter of the approximate circle of the fusion ring is calculated. As illustrated in FIG. 6, the diameter measurement line SL₀ intersecting the two points on the fusion ring FR (approximate circle) projected on the reference plane PL₀ is set. Then, using a width w₀ between the two intersections p_{L0} and p_{R0} of the FR and the diameter measurement line and a distance h from the crystal center position C₀ to the diameter measurement line SL₀, the diameter D diameter D (=(w²+4h²)^{1/2}) of the fusion ring is calculated. The information on the diameter D of the fusion ring thus obtained by the geometric calculation is not pixels but millimeters, so that unit conversion is not necessary.

The silicon single crystal during the crystal pull-up process is thermally expanded under high temperature, so that its diameter is larger than the diameter when it is taken out from the chamber 19 and cooled down. When the diameter of a silicon single crystal is controlled based on such a thermally expanded crystal diameter, it is difficult to make the crystal diameter under room temperature become the target diameter.

Therefore, in the diameter control of the silicon single crystal during the crystal pull-up process, the diameter of the silicon single crystal under high temperature appearing in the image taken by the camera 18 is converted into the diameter under room temperature, and crystal growth conditions such as a crystal pull-up rate are controlled based on the crystal diameter under room temperature. The reason for controlling the crystal pull-up conditions based on the crystal diameter under room temperature is that it is important to control the crystal diameter under room temperature. That is, in a case where the diameter raised to a target diameter under high temperature becomes smaller than the target diameter when the temperature is returned to room temperature, it may not be possible to commercialize the product. Therefore, the diameter control is performed so that the crystal diameter under room temperature reaches the target diameter.

The diameter of the silicon single crystal under room temperature can be obtained by subtracting a predetermined correction amount from the diameter of the single crystal obtained from the fusion ring under high temperature. Alternatively, the diameter of the silicon single crystal under room temperature may be obtained by multiplying the diameter of the single crystal obtained from the fusion ring under high temperature by a predetermined correction coefficient. The correction amount or correction coefficient at this time differs depending on the in-furnace structure and is thus set individually for each single crystal pull-up device. When the in-furnace structure changes with the crystal growth, the correction amount or the correction coefficient may be changed according to the crystal growth. Further, the correction amount or correction coefficient of the crystal diameter may be changed according to the change in the liquid level position of the silicon melt, or may be set according to the pull-up length of the single crystal. Therefore, for example, in the first half of the crystal pull-up step, a certain correction amount may be used to correct the crystal diameter, and in the second half of the crystal pull-up step, another correction amount may be used to correct the crystal diameter. By doing so, the crystal diameter under room temperature can be estimated more accurately.

When the crystal diameter under room temperature is to be calculated by subtracting a predetermined correction amount from the measurement result of the crystal diameter acquired from the camera, the correction amount is calculated ahead of time based on the measurement result of the crystal diameter during the pull-up process acquired from the camera and the measurement result of the crystal diameter measured under room temperature, which measurement results are obtained for the same crystal. Further, when the crystal diameter under room temperature is to be obtained by multiplying the crystal diameter measurement result acquired from the camera by a predetermined correction coefficient, the correction coefficient is calculated ahead of time based on the measurement result of the crystal diameter during the pull-up process acquired from the camera and the measurement result of the crystal diameter measured under room temperature, which measurement results are obtained for the same crystal. In any of the above methods, the correction amount or the correction coefficient is calculated at the diameter measurement positions that match in the crystal longitudinal direction in consideration of the extending amount of the single crystal in the longitudinal direction due to thermal expansion during the crystal pull-up process.

The following describes a method of calculating the liquid level position of the silicon melt, which is the reference plane when the fusion ring is projected and converted.

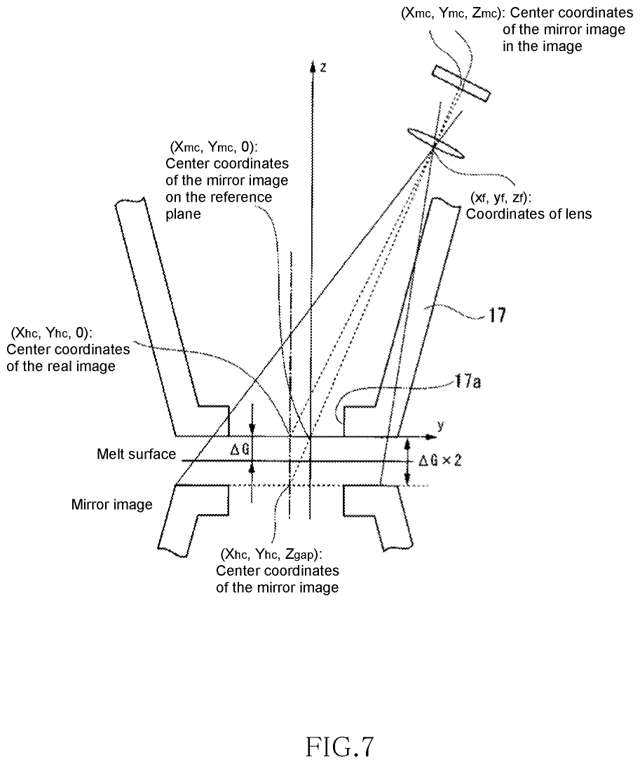

FIG. 7 is a schematic diagram for explaining a method of calculating the gap value ΔG from radii r_{f} and rₘ of the respective openings in the real image Ma and mirror image Mb of the heat shield member 17.

As illustrated in FIG. 7, when the heat shield member 17 is installed horizontally, the center coordinates of the mirror image of the heat shield member 17 originally exist on the opposite side of the center coordinates (X_{hc}, Y_{hc}, 0) of the real image of the heat shield member 17 with respect to the melt surface 13a, and the straight line connecting the two points passes through the center coordinates (X_{hc}, Y_{hc}, 0) of the real image of the heat shield member 17 and is parallel to the Z axis which is the vertical axis.

On the other hand, the center coordinates (X_{mc}, Y_{mc}, 0) of the mirror image of the heat shield member 17 on the reference plane are coordinates obtained by projecting the center coordinates (X_{mc}, Y_{mc}, Z_{gap}) of the mirror image of the heat shield member 17 on the reference plane, so that the center coordinates (X_{hc}, Y_{hc}, Z_{gap}) of the mirror image are on a straight line passing through the center coordinates (X_{mc}, Y_{mc}, 0) of the mirror image of the heat shield member 17 on the reference plane and the center position F (X_{f}, Y_{f}, Z_{f}) of the lens 18b. Therefore, the gap ΔG to be calculated is half the value of Zgap and can be calculated from the following equation (14).

[Numeral 14]

−2ΔG=Z_{gap}=z_{f}−2z_{f}(Y_{mc}−y_{f})/(Y_{hc}−y_{f}) (14)

When the distance from the center position F of the lens 18b of the imaging device to the center of the opening in the real image of the heat shield member 17 is L_{f}, and the distance from the center position F of the lens 18b of the imaging device to the center of the opening in the mirror image of the heat shield member 17 is Lₘ, the distances L_{f} and Lₘ are represented by the following equation (15).

$$\begin{matrix}[ Numeral 15 ] & \\ \begin{matrix}{L}_{f} = {Z}_{f} / cos {θ}_{c} \\ {L}_{m} = ( {Z}_{f} + 2 Δ G ) / cos {θ}_{c}\end{matrix} \} & ( 15 )\end{matrix}$$

From these distances L_{f} and Lₘ, the gap value ΔG can be represented by the following equation (16).

[Numeral 16]

2ΔG=(Lₘ−L_{f})cos θ_{c} (16)

As described above, it can be seen that the distances L_{f} and Lₘ should be obtained in order to calculate the gap value ΔG.

The mirror image of the heat shield member 17 reflected in the melt surface 13a can be considered to be more distant by 2ΔG than the actual heat shield member 17, so that the radius rₘ of the mirror image of the heat shield member 17 looks smaller than the radius r_{f} of the real image of the heat shield member 17. Further, it is known that the size of the opening of the heat shield member 17 is larger under an in-furnace temperature environment during the crystal pull-up process than under room temperature due to thermal expansion. Therefore, when the radius (theoretical value) of the opening in consideration of the thermal expansion is r_{actual}, the radius measurement value of the opening in the real image of the heat shield member 17 is r_{f}, and the radius measurement value of the opening in the mirror image of the heat shield member 17 is rm, the distances L_{f} and Lₘ can be calculated by the following equation (17).

$$\begin{matrix}[ Numeral 17 ] & \\ \begin{matrix}{L}_{f} = ( {r}_{actual} / {r}_{f} ) {L}_{c} \\ {L}_{m} = ( {r}_{actual} / {r}_{m} ) {L}_{c}\end{matrix} \} & ( 17 )\end{matrix}$$

From the above equations (16) and (17), the gap value ΔG can be calculated by the following equation (18).

[Numeral 18]

2ΔG=L_{c}(r_{actual}/rₘ−r_{actual}/r_{f})cos θ_{c} (18)

Thus, the gap value ΔG can be obtained from the radius measurement values r_{f} and rₘ of the openings of the respective real and mirror images of the heat shield member 17.

As described above, the silicon single crystal manufacturing method according to the present embodiment includes a photographing step of photographing the fusion ring generated at the boundary between the silicon melt and the silicon single crystal with the camera and a crystal diameter calculating step of calculating the diameter of a silicon single crystal by processing the image taken by the camera. The crystal diameter calculating step projects and converts the fusion ring appearing in the image taken by the camera on the reference plane corresponding to the liquid level position of the melt based on the installation angle θ_{c} and focal length fₗ of the camera and calculates the diameter of the single crystal from the shape of the fusion ring on the reference plane. Thus, it is possible to accurately calculate the actual diameter of the single crystal without using a diameter conversion coefficient for unit-converting the diameter measurement value obtained from the image taken by the camera. Thus, the crystal diameter can be accurately measured and controlled in the crystal pull-up process, whereby the production yield of the silicon single crystal can be increased.

While the preferred embodiments of the present invention have been described above, the present invention is not limited to the above embodiments, and various modifications may be made within the scope of the present invention, and all such modifications are included in the present invention.

For example, in the above embodiment, the manufacture of a silicon single crystal is taken as an example; however, the present invention is by no means limited to this, and can be applied to the manufacture of various single crystals grown by the CZ method.

### REFERENCE SIGNS LIST

10 single crystal
11 quartz glass crucible
12 heater
13 silicon melt
13a melt surface
14 seed crystal
15 silicon single crystal (ingot)
15a neck section
15b shoulder section
15c straight body section
15d tail section
16 crucible support (graphite crucible)
17 heat shield member (shielding cylinder)
17a opening of the heat shield member
18 camera
18a imaging device
18b lens
19 chamber
21 crucible lift device
22 pull-up drive
24 computer
26 controller

1. A single crystal manufacturing apparatus comprising:
a single crystal puller pulling up a single crystal from a melt;
a camera photographing a fusion ring generated at the boundary between the melt and the single crystal; and
an computer processing a photographed image taken by the camera, wherein
the computer projects and converts the fusion ring appearing in the photographed image taken by the camera on a reference plane corresponding to the liquid level position of the melt based on an installation angle and a focal length of the camera and calculates a diameter of the single crystal from a shape of the fusion ring on the reference plane.

2. The single crystal manufacturing apparatus as claimed in claim 1, wherein
the computer projects and converts an edge pattern of the fusion ring detected based on a predetermined threshold value for the brightness distribution of the photographed image on the reference plane.

3. The single crystal manufacturing apparatus as claimed in claim 2, wherein
the threshold value is a value obtained by multiplying the peak value of brightness in the photographed image by a value smaller than 1, and
the computer sets, in the photographed image, a horizontal scanning line intersecting the fusion ring and detects an outer intersection between brightness distribution on the horizontal scanning line and the threshold value as the edge pattern of the fusion ring.

4. The single crystal manufacturing apparatus as claimed in claim 2, wherein
the computer calculates the diameter of the single crystal based on a distance between two intersections of the edge pattern of the fusion ring projected on the reference plane and a predetermined diameter measurement line and a distance from the center position of the single crystal to the diameter measurement line.

5. The single crystal manufacturing apparatus as claimed in claim 2, wherein
the computer approximates the edge pattern of the fusion ring to a circle and calculates the diameter of the single crystal from the diameter of the approximate circle of the fusion ring.

6. The single crystal manufacturing apparatus as claimed in claim 1, wherein
the computer calculates the diameter of the crystal under room temperature by subtracting a predetermined correction amount from the diameter during the pull-up process of the single crystal or multiplying the diameter during the pull-up process of the single crystal by a predetermined correction coefficient.

7. The single crystal manufacturing apparatus as claimed in claim 6, wherein
the computer changes the correction amount or the correction coefficient according to a change in the furnace structure, the position of the liquid level, or the length of the single crystal.

8. A manufacturing method of a single crystal by a CZ method comprising:
a step of photographing a fusion ring generated at the boundary between a melt and a single crystal with a camera; and
a step of calculating a diameter of the single crystal by processing a photographed image taken by the camera, wherein
the step of calculating the diameter of the single crystal projects and converts the fusion ring appearing in the photographed image taken by the camera on a reference plane corresponding to the liquid level position of the melt based on an installation angle and a focal length of the camera and calculates the diameter of the single crystal from a shape of the fusion ring on the reference plane.

9. The manufacturing method as claimed in claim 8, wherein
the step of calculating the diameter of the single crystal projects and converts an edge pattern of the fusion ring detected based on a predetermined threshold value with respect to the brightness distribution of the photographed image on the reference plane.

10. The manufacturing method as claimed in claim 9, wherein
the threshold value is a value obtained by multiplying the peak value of brightness in the photographed image by a value smaller than 1, and
the step of calculating the diameter of the single crystal sets, in the photographed image, a horizontal scanning line intersecting the fusion ring and detects an outer intersection (one point near the outer periphery of the photographed image) between brightness distribution on the horizontal scanning line and the threshold value as the edge pattern of the fusion ring.

11. The manufacturing method as claimed in claim 9, wherein
the step of calculating the diameter of the single crystal calculates the diameter of the single crystal based on a distance between two intersections of the edge pattern of the fusion ring projected on the reference plane and a predetermined diameter measurement line and a distance from the center position of the single crystal to the diameter measurement line.

12. The manufacturing method as claimed in claim 9, wherein
the step of calculating the diameter of the single crystal approximates the edge pattern of the fusion ring to a circle and calculates the diameter of the single crystal from the diameter of the approximate circle of the fusion ring.

13. The manufacturing method as claimed in claim 8, wherein
the step of calculating the diameter of the single crystal calculates the diameter of the crystal under room temperature by subtracting a predetermined correction amount from the diameter during the pull-up process of the single crystal or multiplying the diameter during the pull-up process of the single crystal by a predetermined correction coefficient.

14. The manufacturing method as claimed in claim 13, wherein
the step of calculating the diameter of the single crystal changes the correction amount or the correction coefficient according to a change in the furnace structure, the position of the liquid level, or the length of the single crystal.
